(19) United States
(12) Patent Application Publication
(10) Pub. No.: US 2023/0259032 A1
(43) Pub. Date: Aug. 17, 2023

(54) COMPOSITION, UNDERLAYER FILM, AND DIRECTED SELF-ASSEMBLY LITHOGRAPHY PROCESS

(71) Applicant: JSR CORPORATION, Tokyo (JP)

(72) Inventors: Miki TAMADA, Tokyo (JP); Ryo KUMEGAWA, Tokyo (JP); Hiroyuki KOMATSU, Tokyo (JP); Motohiro SHIRATANI, Tokyo (JP); Ken MARUYAMA, Tokyo (JP); Sosuke OSAWA, Tokyo (JP)

(73) Assignee: JSR CORPORATION, Tokyo (JP)

(21) Appl. No.: 18/138,873

(22) Filed: Apr. 25, 2023

Related U.S. Application Data
(63) Continuation-in-part of application No. PCT/JP2021/037326, filed on Oct. 8, 2021.

(30) Foreign Application Priority Data
Nov. 10, 2020 (JP) 2020-187241

(51) Int. Cl. G03F 7/11; C08F 112/08; C08F 120/14; C09D 125/06; C09D 133/12

(52) U.S. Cl. CPC G03F 7/11; C08F 112/08; C08F 120/14; C09D 125/06; C09D 133/12; C08F 2810/40

(57) ABSTRACT

A composition includes: at least one polymer represented by formula (1), formula (2), or both; and a solvent. A¹ and A² are each independently a structural unit having 2 or more carbon atoms; a plurality of A's are the same or different and a plurality of A²s are the same or different; n1 and n2 are each independently an integer of 2 to 500; R¹, R², and R³ are each independently an organic group having 1 or more carbon atoms, or R¹ and R² taken together represent a ring together with X¹, Y¹, and P; R¹ and R² are the same or different; X¹, Y¹, and Y² are each independently a single bond, —O—, or —NR⁴—; R⁴ is an organic group having 1 or more carbon atoms; and Z¹ and Z² are each independently hydrogen or an organic group having 1 to 15 carbon atoms.

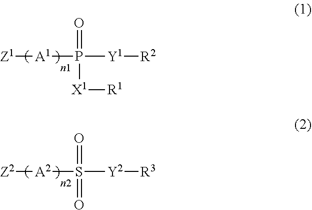

### CROSS-REFERENCE TO RELATED APPLICATIONS

The present application is a continuation-in-part application of International Patent Application No. PCT/JP2021/037326 filed Oct. 8, 2021, which claims priority to Japanese Patent Application No. 2020-187241 filed Nov. 10, 2020. The contents of these applications are incorporated herein by reference in their entirety.

### BACKGROUND OF THE DISCLOSURE

### Technical Field

The present disclosure relates to a composition, an underlayer film, a directed self-assembly lithography process.

### Background Art

Miniaturization of structures of various types of electronic devices such as semiconductor devices and liquid crystal devices has been accompanied by demands for miniaturization of patterns in lithography processes. Today, although fine patterns having a line width of about 90 nm can be formed using, for example, an ArF excimer laser, finer pattern formation is required.

To meet such demands described above, a lithography process which utilizes a phase separation structure due to so-called directed self-assembly that spontaneously forms an ordered pattern has been proposed. As such a directed self-assembly lithography process, a method of forming an ultrafine pattern by directed self-assembly using a block copolymer obtained by copolymerizing monomers differing in properties from each other is known (see JP-A-2008-149447, JP-A-2002-519728, and JP-A-2003-218383). When this method is used, annealing of a film containing the block copolymer results in a tendency of clustering of polymer structures having the same property, and thus a pattern can be formed in a self-aligning manner. In addition, a method of forming a fine pattern by directed self-assembling a composition containing a plurality of polymers differing in properties from each other is also known (see US 2009/0214823 A1 and JP-A-2010-058403).

It is known that in such a directed self-assembly lithography process, phase separation by the above-described directed self-assembly is effectively caused by forming a film containing such a component as a polymer to be self-assembled on a specific underlayer film. Various studies have been made on that underlayer film, and it is known that various phase separation structures can be formed by appropriately controlling the surface free energy of an underlayer film when a block copolymer is directed self-assembled (see JP-A-2008-36491 and JP-A-2012-174984). As a polymer to constitute such an underlayer film, for example, a random copolymer composed of two types of monomers having different compositions such as styrene and methyl methacrylate has been proposed.

### SUMMARY OF THE DISCLOSURE

According to an aspect of the present disclosure, a composition includes: at least one polymer which is a polymer represented by formula (1), a polymer represented by formula (2), or both; and a solvent. A¹ and A² are each independently a structural unit having 2 or more carbon atoms; a plurality of A's are the same or different and a plurality of A²s are the same or different; n1 and n2 are each independently an integer of 2 to 500; R¹, R², and R³ are each independently an organic group having 1 or more carbon atoms, or R¹ and R² taken together represent a ring together with X¹, Y¹, and P; R¹ and R² are the same or different; X¹, Y¹, and Y² are each independently a single bond, —O—, or —NR⁴—; R⁴ is an organic group having 1 or more carbon atoms; and Z¹ and Z² are each independently hydrogen or an organic group having 1 to 15 carbon atoms.

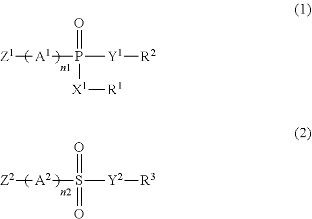

According to another aspect of the present disclosure, an underlayer film of a directed self-assembled film in a directed self-assembly lithography process, is formed from the above-described composition.

According to a further aspect of the present disclosure, a directed self-assembly lithography process includes forming an underlayer film by applying the above-described composition directly or indirectly on one surface of a substrate. A composition for directed self-assembled film formation is applied to a surface of the underlayer film on a side opposite the substrate to form a coating film on the underlayer film. The coating film is phase-separated to form a directed self-assembled film having a plurality of phases. At least part of the plurality of phases of the directed self-assembled film is removed to form a pattern.

### BRIEF DESCRIPTION OF THE DRAWINGS

A more complete appreciation of the disclosure and many of the attendant advantages thereof will be readily obtained as the same becomes better understood by reference to the following detailed description when considered in connection with the accompanying drawings, wherein:

FIG. 1 is a schematic cross-sectional view illustrating an embodiment example of a state after an underlayer film is formed in the directed self-assembly lithography process of the embodiment of the present invention.

FIG. 2 is a schematic cross-sectional view illustrating an embodiment example of a state after a pre-pattern is formed on an underlayer film in the directed self-assembly lithography process of the embodiment of the present invention.

FIG. 3 is a schematic cross-sectional view illustrating an embodiment example of a state after a pre-pattern is transferred to an underlayer film in the directed self-assembly lithography process of the embodiment of the present invention.

FIG. 4 is a schematic cross-sectional view illustrating an embodiment example of a state after neutralization films are formed, for example, between underlayer films to which a pre-pattern has been transferred, in the directed self-assembly lithography process of the embodiment of the present invention.

FIG. 5 is a schematic cross-sectional view illustrating an embodiment example of a state after a directed self-assembled film with a phase separation structure is formed on underlayer films and neutralization films, in the directed self-assembly lithography process of the embodiment of the present invention.

FIG. 6 is a schematic cross-sectional view illustrating an embodiment example of a state after some phases of a directed self-assembled film are removed in the directed self-assembly lithography process of the embodiment of the present invention.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

The study by the present inventors has revealed that the metal substrate may be corroded by a composition for a base that forms an underlayer film.

That is, an embodiment of the present invention relates to:

a composition for underlayer film formation containing at least one polymer selected from a polymer represented by the following formula (1) (hereinafter may be referred to as “polymer (1)”) and a polymer represented by the following formula (2) (hereinafter may be referred to as “polymer (2)”), and a solvent,

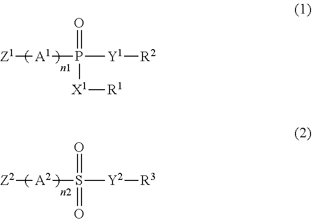

in the formulas (1) and (2),

A¹ and A² are each a structural unit having 2 or more carbon atoms; a plurality of A's and a plurality of A²s each may be the same or different;

n1 and n2 are each an integer of 2 to 500;

R¹, R², and R³ are each an organic group having 1 or more carbon atoms, or R¹ and R² are bonded to each other to form a ring together with X¹, Y¹, and P; R¹ and R² may be the same or different;

X¹, Y¹, and Y² are each independently a single bond, —O—, or —NR⁴—; R⁴ is an organic group having 1 or more carbon atoms; and Z¹ and Z² are each hydrogen or an organic group having 1 to 12 carbon atoms.

In the present disclosure, examples of the organic group include a monovalent hydrocarbon group, a group containing a divalent hetero atom-containing group between two adjacent carbon atoms of the monovalent hydrocarbon group, and groups resulting from the hydrocarbon group and the group containing a divalent hetero atom-containing group by substituting some or all of the hydrogen atoms contained therein with a monovalent hetero atom-containing group.

In the present disclosure, the “hydrocarbon group” includes a chain hydrocarbon group, an alicyclic hydrocarbon group, and an aromatic hydrocarbon group. The “hydrocarbon group” includes both a saturated hydrocarbon group and an unsaturated hydrocarbon group. The “chain hydrocarbon group” refers to a hydrocarbon group that does not include any cyclic structure and is composed only of a chain structure, and includes both a linear hydrocarbon group and a branched hydrocarbon group. The “alicyclic hydrocarbon group” refers to a hydrocarbon group that includes only an alicyclic structure as a ring structure and does not include any aromatic ring structure and includes both a monocyclic alicyclic hydrocarbon group and a polycyclic alicyclic hydrocarbon group. However, it is not necessary for the alicyclic hydrocarbon group to be composed only of an alicyclic structure, and the alicyclic hydrocarbon group may include a chain structure in a part thereof. The “aromatic hydrocarbon group” refers to a hydrocarbon group that includes an aromatic ring structure as a ring structure. However, it is not necessary for the aromatic hydrocarbon group to be composed only of an aromatic ring structure, and the aromatic hydrocarbon group may include a chain structure or an alicyclic structure in a part thereof.

Since the composition for underlayer film formation of the embodiment of the present invention contains the polymer (1) or the polymer (2), it is possible to form an underlayer film which is superior in alignment orientation, and forms a phase separation structure with few defects, and is superior in adsorbability to a metal substrate and non-corrosiveness to a substrate.

Another embodiment of the present invention relates to an underlayer film of a directed self-assembled film in a directed self-assembly lithography process which is formed of the composition for underlayer film formation.

Since the underlayer film of the embodiment is formed of a composition for underlayer film formation containing the polymer (1) or the polymer (2), the underlayer film can form a phase separation structure with superior alignment orientation due to directed self-assembly and can be superior in adsorbability to a metal substrate and non-corrosiveness to a substrate.

A further embodiment of the present invention relates to

a directed self-assembly lithography process including:

a step (1) of forming an underlayer film on one surface of a substrate using the above-described composition for underlayer film formation;

a step (2) of applying a composition for directed self-assembled film formation to a surface of the underlayer film on a side opposite the substrate;

a step (3) of phase-separating the coating film formed in the application step; and

a step (4) of removing at least part of the phases of the directed self-assembled film formed in the phase separation step.

Since the directed self-assembly lithography process of the embodiment includes a step in which the composition for underlayer film formation is used, it is possible to utilize the process in order, for example, to form a good pattern that is superior in defect performance or the like by using the phase separation structure due to directed self-assembly and that is superior in adsorbability to a metal substrate and non-corrosiveness to a substrate and also superior in alignment orientation.

Hereinbelow, embodiments of the present invention will specifically be described, but the present invention is not limited to these embodiments.

### <Composition for Underlayer Film Formation>

The composition for underlayer film formation of the embodiment of the present invention contains a polymer represented by the formula (1) or (2) and a solvent.

The composition for underlayer film formation may further contain other optional components as long as the action and effect of the present invention are not impaired.

### (Polymers (1) and (2))

In the embodiment of the present invention, the polymer (1) and the polymer (2) are represented by the formula (1) or (2).

Since the composition for underlayer film formation in the embodiment of the present invention contains the polymer (1) or the polymer (2), it is possible, in a directed self-assembly lithography process, to form a phase separation structure with few defects superior in alignment orientation, and form an underlayer film superior in adsorbability to a metal substrate and in non-corrosiveness to a substrate.

In the formulas (1) and (2), A¹ and A² are each a structural unit having 2 or more carbon atoms. A plurality of A's and a plurality of A²s each may be the same or different.

More specifically, for example, A¹ in the formula (1) or A² in the formula (2) preferably includes, as a monomer unit, a structural unit derived from styrene, a structural unit derived from a (meth)acrylate ester, a structural unit derived from vinylpyridine, or any two or more of these.

In the formulas (1) and (2), n1 and n2 are each an integer of 2 to 500. n1 and n2 are each preferably 10 or more, and more preferably 20 or more. In addition, n1 and n2 are preferably 400 or less, and more preferably 300 or less. When the values of n1 and n2 falls within the above range, the alignment orientation of the phase separation structure due to directed self-assembly using the underlayer film can be further improved.

In the above formulas (1) and (2), R¹, R², and R³ are each an organic group having 1 or more carbon atoms, or R¹ and R² are bonded to each other to form a ring together with X¹, Y¹, and P. R¹ and R² may be the same or different.

Examples of the organic group having one or more carbon atoms in R¹, R², and R³ in the above formulas (1) and (2) include a monovalent hydrocarbon group, a group containing a divalent hetero atom-containing group between two adjacent carbon atoms of the monovalent hydrocarbon group, and groups resulting from the hydrocarbon group and the group containing a divalent hetero atom-containing group by substituting some or all of the hydrogen atoms contained therein with a monovalent hetero atom-containing group. As the organic group having 1 or more carbon atoms, organic groups having 1 to 20 carbon atoms are preferable, and organic groups having 1 to 12 carbon atoms are more preferable.

Examples of the hydrocarbon group include monovalent chain hydrocarbon groups having 1 to 20 carbon atoms. More specifically, examples of the hydrocarbon group include alkyl groups such as a methyl group, an ethyl group, a n-propyl group, and an i-propyl group; alkenyl groups such as an ethenyl group, a propenyl group, and a butenyl group; and alkynyl groups such as an ethynyl group, a propynyl group, and a butynyl group.

Furthermore, examples of the hydrocarbon group include monovalent alicyclic hydrocarbon groups having 3 to 20 carbon atoms. More specifically, examples of the hydrocarbon group include monocyclic alicyclic saturated hydrocarbon groups such as a cyclopentyl group and a cyclohexyl group, monocyclic alicyclic unsaturated hydrocarbon groups such as a cyclopentenyl group and a cyclohexenyl group, polycyclic alicyclic saturated hydrocarbon groups such as a norbornyl group, an adamantyl group and a tricyclodecyl group, and polycyclic alicyclic unsaturated hydrocarbon groups such as a norbornenyl group and a tricyclodecenyl group.

Furthermore, examples of the hydrocarbon group include monovalent aromatic hydrocarbon groups having 6 to 20 carbon atoms. More specifically, examples of the hydrocarbon group include aryl groups such as a phenyl group, a tolyl group, a xylyl group, a naphthyl group, and an anthryl group; and aralkyl groups such as a benzyl group, a phenethyl group, a naphthylmethyl group, and an anthrylmethyl group.

Examples of the hetero atom constituting the monovalent and divalent hetero atom-containing groups include an oxygen atom, a nitrogen atom, a sulfur atom, a phosphorus atom, a silicon atom, and a halogen atom. Examples of the halogen atom include a fluorine atom, a chlorine atom, a bromine atom, and an iodine atom.

Examples of the divalent hetero atom-containing group include —O—, —CO—, —S—, —CS—, —NR′—, and groups in which two or more of the foregoing are combined. R′ is a hydrogen atom or a monovalent hydrocarbon group.

Examples of the monovalent hetero atom-containing group include halogen atoms such as a fluorine atom, a chlorine atom, a bromine atom, and an iodine atom; a hydroxyl group, a carboxyl group, a cyano group, an amino group, and a sulfanyl group.

In the formulas (1) and (2), X¹, Y¹, and Y² are each independently a single bond, —O—, or —NR⁴—. R⁴ is an organic group having 1 or more carbon atoms.

R⁴ is, for example, an organic group having 1 to 20 carbon atoms, and the definition of the organic group is the same as that of the organic group having 1 or more carbon atoms in R¹, R², and R³.

When R¹ and R² are bonded to each other to form a ring together with X¹, Y¹, and P, a heterocyclic structure having 5 or more ring members is formed.

In the formulas (1) and (2), Z¹ and Z² each represent hydrogen or an organic group having 1 to 15 carbon atoms. Examples thereof include a methyl group, an ethyl group, a n-butyl group, a sec-butyl group, a t-butyl group, a cyclohexyl group, a phenyl group, and a pentadecyl group.

The polymer (1) and the polymer (2) can be synthesized, for example, as a homopolymer, a random copolymer, an alternating copolymer, or the like, using monomers that will afford respective structural units and a polymerization initiator.

The molecular weight of the polymer (1) and the polymer (2) is not particularly limited, and their weight average molecular weight (Mw) as determined by Gel Permeation Chromatography (GPC) relative to standard polystyrene is preferably 1,000 to 50,000, more preferably 2,000 to 30,000, even more preferably 3,000 to 20,000, and particularly preferably 4,000 to 17,000. When the Mw of the polymer (1) and the polymer (2) falls within the above range, the film formability and heat resistance of the resulting underlayer film can be further improved.

The molecular weight distribution (Mn/Mw) of the polymer (1) and the polymer (2) is preferably 1.50 or less, preferably 1 to 1.30, more preferably 1 to 1.25, and even more preferably 1 to 1.2. When the Mn and the Mw/Mn of the polymer (1) fall within the above ranges, the alignment orientation of the phase separation structure due to directed self-assembly using the underlayer film can be further improved.

The Mw and the Mn of a resin in the present description are values measured using gel permeation chromatography (GPC) under the following conditions.

GPC column: two G2000HXL, one G3000HXL, one G4000HXL (all manufactured by Tosoh Corporation)

Column temperature: 40° C.

Elution solvent: tetrahydrofuran

Flow rate: 1.0 mL/min

Sample concentration: 1.0% by mass

Amount of sample injected: 100 μL

Detector: differential refractometer

Standard substance: monodisperse polystyrene

### (Solvent)

The composition for underlayer film formation contains a solvent. The solvent is not particularly limited as long as it is a solvent capable of dissolving or dispersing at least the polymer (1), the polymer (2), and the like.

Examples of the solvent include an alcohol-based solvent, an ether-based solvent, a ketone-based solvent, an amide-based solvent, an ester-based solvent, and a hydrocarbon-based solvent.

Examples of the alcohol-based solvent include aliphatic monoalcohol-based solvents having 1 to 18 carbon atoms such as 4-methyl-2-pentanol and n-hexanol;

alicyclic monoalcohol-based solvent having 3 to 18 carbon atoms such as cyclohexanol;

polyhydric alcohol-based solvent having 2 to 18 carbon atoms such as 1,2-propylene glycol; and

polyhydric alcohol partial ether-based solvents having 3 to 19 carbon atoms such as propylene glycol monomethyl ether.

Examples of the ether-based solvent include dialkyl ether-based solvents such as diethyl ether, dipropyl ether, dibutyl ether, dipentyl ether, diisoamyl ether, dihexyl ether, and diheptyl ether;

cyclic ether-based solvents such as tetrahydrofuran and tetrahydropyran; and

aromatic ring-containing ether-based solvents such as diphenyl ether and anisole.

Examples of the ketone-based solvent include chain ketone-based solvents, such as acetone, methyl ethyl ketone, methyl-n-propyl ketone, methyl-n-butyl ketone, diethyl ketone, methyl-iso-butyl ketone, 2-heptanone, ethyl-n-butyl ketone, methyl-n-hexyl ketone, di-iso-butyl ketone, and trimethylnonanone;

cyclic ketone-based solvents, such as cyclopentanone, cyclohexanone, cycloheptanone, cyclooctanone, and methylcyclohexanone; and

2,4-pentanedione, acetonylacetone, and acetophenone.

Examples of the amide-based solvent include a cyclic amide-based solvent, such as N,N′-dimethylimidazolidinone and N-methylpyrrolidone; and

a chain amide-based solvent, such as N-methylformamide, N,N-dimethylformamide, N,N-diethylformamide, acetamide, N-methylacetamide, N,N-dimethylacetamide, and N-methylpropionamide.

Examples of the ester-based solvent include acetate ester-based solvents such as n-butyl acetate;

monocarboxylate ester-based solvents such as lactate ester-based solvents such as ethyl lactate and butyl lactate;

polyhydric alcohol carboxylate-based solvents such as propylene glycol acetate;

polyhydric alcohol partial ether carboxylate-based solvents such as propylene glycol monomethyl ether acetate;

polyvalent carboxylate diester-based solvents such as diethyl oxalate; and

carbonate-based solvents such as dimethyl carbonate, diethyl carbonate, ethylene carbonate, and propylene carbonate.

Examples of the hydrocarbon-based solvent include aliphatic hydrocarbon-based solvents having 5 to 12 carbon atoms such as n-pentane and n-hexane; and

aromatic hydrocarbon-based solvents having 6 to 16 carbon atoms such as toluene and xylene.

As the solvent, for example, an ester-based solvent is preferable, a polyhydric alcohol partial ether carboxylate-based solvent and/or a lactate ester-based solvent is more preferable, and propylene glycol monomethyl ether acetate and/or ethyl lactate is even more preferable.

The composition for underlayer film formation may contain one or two or more of the solvents disclosed above.

### (Other Optional Components)

The composition for underlayer film formation may contain other optional components in addition to the components described above. Examples of the other optional components include a surfactant and a crosslinking agent. The surfactant is a component capable of improving the coating characteristics of the composition for underlayer film formation. When a crosslinking agent is contained, a crosslinking reaction of the crosslinking agent with the polymer (1) and the polymer (2) occurs, and the heat resistance of an underlayer film to be formed can be improved. The composition for underlayer film formation may contain an acid generator that generates an acid through exposure to light or heating. Such other optional components may be used singly or two or more types thereof may be used in combination.

Since the composition for underlayer film formation of the embodiment of the present invention has the above characteristics, it can be particularly suitably used for underlayer film formation treatment onto a silicon-containing substrate in a directed self-assembly lithography process.

In addition, since the composition for underlayer film formation of the embodiment of the present invention has the above characteristics, it can be particularly suitably used for underlayer film formation treatment onto a metal-containing film in a directed self-assembly lithography process.

### (Method for Preparing Composition for Underlayer Film Formation)

The composition for underlayer film formation of the embodiment of the present invention can be prepared, for example, by mixing the polymer (1) or the polymer (2), a solvent, and optional components as necessary in a prescribed ratio, and preferably filtering the resulting mixture through, for example, a filter having pores as large as about 0.45 μm. The lower limit of the solid concentration of the composition for underlayer film formation is preferably 0.1% by mass, more preferably 0.5% by mass, even more preferably 0.8% by mass, and particularly preferably 1% by mass. The upper limit of the solid concentration is preferably 50% by mass, more preferably 30% by mass, even more preferably 10% by mass, and particularly preferably 5% by mass.

In addition, a known method can be appropriately used in the adjustment of the composition for underlayer film formation.

### <Underlayer Film>

The underlayer film of the embodiment of the present invention is an underlayer film of a directed self-assembled film in a directed self-assembly lithography process which is formed of the composition for underlayer film formation.

Since the underlayer film of the embodiment of the present invention is formed of the composition for underlayer film formation containing the polymer (1) or the polymer (2) having a partial structure represented by the formula (1) or (2), it is possible to form a phase separation structure with superior alignment orientation due to directed self-assembly.

For the formation of the underlayer film, a known method can be appropriately used using the composition for underlayer film formation. For example, the method described in the section of the directed self-assembly lithography process and the like can be employed.

### <Directed Self-Assembly Lithography Process>

The directed self-assembly lithography process of the embodiment of the present invention includes:

a step (1) of forming an underlayer film on one surface of a substrate using the composition for underlayer film formation,

a step (2) of applying a composition for directed self-assembled film formation to a surface of the underlayer film on a side opposite the substrate,

a step (3) of phase-separating the coating film formed in the application step, and

a step (4) of removing at least part of the phases of the directed self-assembled film formed in the phase separation step.

Since the directed self-assembly lithography process of the embodiment of the present invention includes a step in which the composition for underlayer film formation is used, it is possible to utilize the process in order, for example, to form a good pattern that is superior in defect performance or the like by using the phase separation structure due to directed self-assembly and that is superior in adsorbability to a metal substrate and non-corrosiveness to a substrate and also superior in alignment orientation.

Directed self-assembly refers to a phenomenon in which a tissue or a structure is spontaneously constructed without being caused only by control from an external factor. In the embodiment of the present invention, a pattern (miniaturized pattern) can be formed by for example, applying a composition for directed self-assembled film formation onto an underlayer film formed from a specific composition for underlayer film formation, thereby forming a film with a phase separation structure due to directed self-assembly (directed self-assembled film), and then removing part of the phases in the directed self-assembled film.

The directed self-assembly lithography process includes: a step (1) of forming an underlayer film on one surface of a substrate using the above-described composition for underlayer film formation (hereinafter also referred to as “underlayer film formation step”); a step (2) of applying a composition for directed self-assembled film formation to a surface of the underlayer film on a side opposite the substrate (hereinafter also referred to as “application step”); a step (3) of phase-separating the coating film formed in the application step (hereinafter also referred to as “phase separation step”); and a step (4) of removing at least part of the phases of the directed self-assembled film formed in the phase separation step (hereinafter also referred to as “removing step”).

In addition, the directed self-assembly lithography process may include, for example, a step (5) of etching the substrate using a pattern formed in the removing step (the step (4)) (hereinafter also referred to as “etching step”).

In addition, the directed self-assembly lithography process can include a step (6) of forming a pre-pattern on a directed self-assembled film-formed surface side of the underlayer film or the substrate prior to the application step (step (2)), a step (7) of etching the substrate using the formed pattern and then removing the pre-pattern (hereinafter also referred to as “transfer step”), and a step (8) of applying a neutralization film to the substrate (hereinafter also referred to as “neutralization film formation step”).

Hereinafter, each step will be described with reference to drawings.

### [Underlayer Film Formation Step]

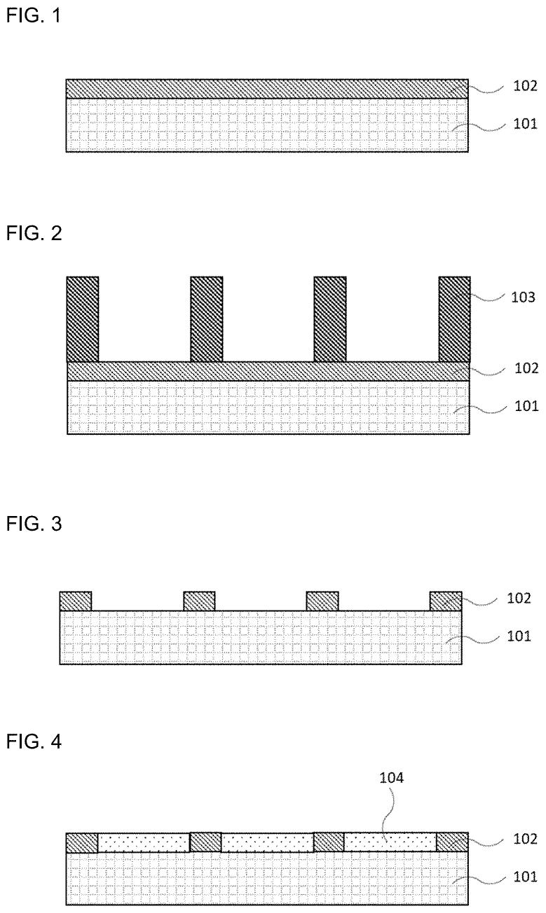

In this step, an underlayer film is formed on one surface of the substrate using the composition for underlayer film formation. As a result, a substrate with an underlayer film in which an underlayer film 102 is formed on the substrate 101 is obtained as illustrated in FIG. 1. The directed self-assembled film is stacked on the underlayer film 102. In the formation of the phase separation structure (microdomain structure) of the directed self-assembled film, it is considered that an interaction between the component constituting the directed self-assembled film and the underlayer film 102 effectively works in addition to an interaction in that component itself, and this makes it possible to control the phase separation structure, and this results in superior alignment orientation of the phase separation structure due to directed self-assembly.

As the substrate 101, for example, a conventionally known substrate such as a silicon-containing substrate such as a silicon wafer or a metal-containing film such as a wafer coated with aluminum can be used. The underlayer film 102 can be formed by curing a coating film formed by applying the composition for underlayer film formation onto the substrate 101 by a known method such as a spin coating method by heating and/or exposure.

Examples of the radiation to be used for the exposure include visible light, ultraviolet rays, far ultraviolet rays, X-rays, electron beams, γ-rays, molecular beams, and ion beams.

As the conditions for forming the underlayer film, the lower limit of the heating temperature of the coating film is preferably 100° C., more preferably 120° C., even more preferably 150° C., and particularly preferably 180° C. The upper limit of the heating temperature is preferably 400° C., more preferably 300° C., even more preferably 240° C., and particularly preferably 220° C. The lower limit of the heating time of the coating film is preferably 10 seconds, more preferably 15 seconds, and even more preferably 30 seconds. The upper limit of the heating time is preferably 30 minutes, more preferably 10 minutes, and even more preferably 5 minutes. When the heating temperature and time in forming the underlayer film fall within the above ranges, an underlayer film can be easily and reliably formed. The atmosphere for heating the coating film may be either an air atmosphere or an inert gas atmosphere such as nitrogen gas.

The lower limit of the average thickness of the underlayer film 102 is preferably 5 nm, more preferably 10 nm, even more preferably 15 nm, and particularly preferably 20 nm. The upper limit of the average thickness is preferably 20,000 nm, more preferably 1,000 nm, even more preferably 500 nm, and particularly preferably 100 nm.

The lower limit of the static contact angle with pure water on a surface of the underlayer film 102 is preferably 60°, more preferably 70°, and even more preferably 75°. The upper limit of the static contact angle is preferably 95°, more preferably 90°, and even more preferably 85°. When the static contact angle of the surface of the underlayer film falls within the above range, the alignment orientation of the phase separation structure due to directed self-assembly can be further improved.

### [Pre-Pattern Formation Step]

In this step, a pre-pattern is formed on a directed self-assembled film-formed surface side of the underlayer film or the substrate. Preferably, a pre-pattern 103 is formed on the underlayer film 102 using a composition for pre-pattern formation as illustrated in FIG. 2. The pre-pattern 103 is provided for the purpose of transferring the pre-pattern to the underlayer film 102. The underlayer film 102 with the pre-pattern transferred is provided for the purpose of controlling phase separation at the time of forming a directed self-assembled film to better form a phase separation structure due to directed self-assembly. That is, among the components forming the directed self-assembled film, a component having high affinity with the underlayer film 102 forms a phase along the underlayer film 102, and a component having low affinity forms a phase at a position away from the pre-pattern. This makes it possible to more clearly form a phase separation structure due to directed self-assembly.

In addition, the phase separation structure to be formed can be finely controlled by the material, length, shape, and the like of the pre-pattern. It is noted that the shape of the pre-pattern can be appropriately chosen according to a pattern intended to be finally formed, and for example, a line-and-space pattern, a hole pattern, a pillar pattern, or the like can be employed.

As a method for forming the pre-pattern 103, the same method as a known method for forming a resist pattern can be used. As the composition for pre-pattern formation, a conventional composition for resist film formation can be used.

As a specific method for forming the pre-pattern 103, for example, a chemically amplified resist composition such as “AEX1191JN” (ArF immersion resist) produced by JSR Corporation is applied onto the underlayer film 102 to form a resist film. Next, a desired region of the resist film is irradiated with radiation through a mask with a specific pattern to perform exposure. Examples of the radiation include electromagnetic waves such as ultraviolet rays, far ultraviolet rays, and X-rays, and charged particle beams such as electron beams. Among them, far ultraviolet rays are preferable, and ArF excimer laser light or KrF excimer laser light is more preferable. Subsequently, post exposure baking (PEB) is conducted, and development is performed using a developer such as an alkaline developer, so that a desired pre-pattern 103 can be formed.

### [Transfer Step]

In this step, a part of the underlayer film 102 is removed by etching using the pattern formed in a resist processing step as a protective film. Thus, a miniaturized pattern is transferred.

FIG. 3 illustrates a state after a part of the underlayer film 102 is removed. Examples of a method for removing a part of the underlayer film 102 include such known methods as reactive ion etching (RIE) such as chemical dry etching; and physical etching such as sputter etching and ion beam etching. Among them, reactive ion etching (RIE) is preferable, and chemical dry etching using CF₄, O₂ gas, or the like is more preferable.

### [Neutralization Film Formation Step]

In this step, the composition for neutralization film formation is applied to, for example, between the underlayer films 102 to which the pattern has been transferred. Examples of the composition for neutralization film formation include a composition in which a component having the same or approximately the same affinity with two phases which the directed self-assembled film forms is dissolved in a solvent or the like.

Examples of the method for applying the composition for neutralization film formation include a spin coating method. As illustrated in FIG. 4, the composition for directed self-assembled film formation is applied to, for example, between patterns of the underlayer film 102, and thus a neutralization film 104 is formed.

### [Application Step]

In this step, the composition for directed self-assembled film formation is applied to surfaces of the underlayer film 102 and the neutralization film 104 on a side opposite from the substrate.

Examples of the composition for directed self-assembled film formation include a composition in which a component capable of forming a phase separation structure by directed self-assembly is dissolved in a solvent or the like.

Examples of the component capable of forming a phase separation structure by the directed self-assembly include a block copolymer and a mixture of two or more polymers incompatible with each other. Among them, from the viewpoint of being able to form a clearer phase separation structure, a block copolymer is preferable, a block copolymer composed of a styrene unit and a methacrylate ester unit is more preferable, and a diblock copolymer composed of a styrene unit and a methyl methacrylate unit is even more preferable.

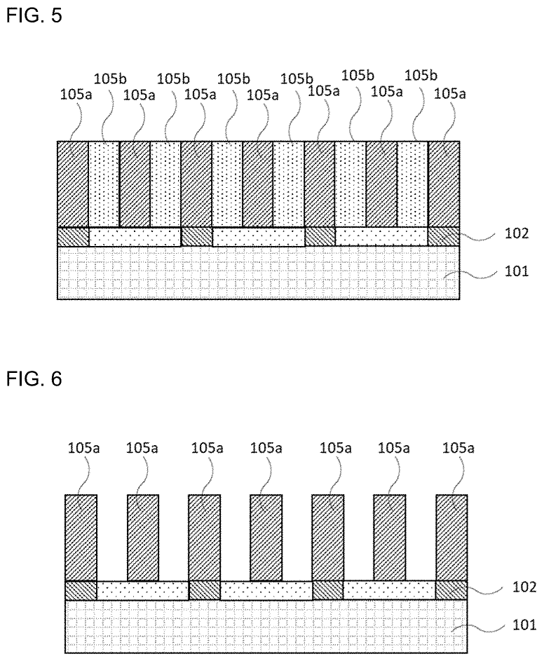

Examples of the method for applying the composition for directed self-assembled film formation include a spin coating method. As illustrated in FIG. 5, the composition for directed self-assembled film formation is applied to the underlayer film 102 and the neutralization film 104, and thus a coating film that will become a directed self-assembled film is formed.

### [Phase Separation Step]

In this step, the coating film formed in the application step is phase-separated. As a result, a directed self-assembled film is formed.

In the phase separation of the coating film of the composition for directed self-assembled film formation, annealing or the like can promote so-called directed self-assembly, in which sites having the same properties are accumulated to spontaneously form an ordered pattern. As a result, a phase separation structure is formed on the underlayer film 102 and the neutralization film 104 as illustrated in FIG. 5. The phase separation structure is preferably formed along the underlayer film 102, and the interface formed by the phase separation is more preferably substantially parallel to the underlayer film 102.

For example, when the underlayer film 102 is in a line pattern, a phase 105a of a component having a higher affinity with the underlayer film 102 is formed above the underlayer film 102, and the components in the coating film on the neutralization film 104 forms a directed self-assembled film having a phase separation structure in which the phase 105a and a phase 105b of the other component are disposed alternately along the phase 105a formed above the underlayer film 102.

When the underlayer film 102 is in a hole pattern, a phase of a component having higher affinity is formed on the underlayer film 102, and a phase of the other component is formed in a hole portion.

Furthermore, when the underlayer film 102 is in a pillar pattern, a phase of a component having higher affinity with the underlayer film 102 is formed in a pillar portion, and a phase of the other component is formed in the other portion. A desired phase separation structure can be formed by appropriately adjusting the distance between the pillars of the pattern of the underlayer film 102, the structure and blending ratio of the components such as each polymer in the directed self-assembly composition, and the like.

The phase separation structure formed includes a plurality of phases, and the interface formed by these phases is usually substantially vertical, but the interface itself is not required to have strict clarity. A resulting phase separation structure can be precisely controlled and a desired fine pattern can be obtained by the structure and blending ratio of the component of each polymer and the pre-pattern in addition to the underlayer film as described above.

Examples of the annealing method include heating with an oven, a hot plate, or the like. The lower limit of the heating temperature is preferably 80° C., and more preferably 100° C. The upper limit of the heating temperature is preferably 400° C., and more preferably 300° C. The lower limit of the annealing time is preferably 10 seconds, and more preferably 30 seconds. The upper limit of the time is preferably 120 minutes, and more preferably 60 minutes.

The lower limit of the average thickness of the resulting directed self-assembled film is preferably 0.1 nm, and more preferably 0.5 nm. The upper limit of the average thickness is preferably 500 nm, and more preferably 100 nm.

### [Removing Step]

In this step, at least part of the phases of the directed self-assembled film formed in the phase separation step is removed. Thus, a miniaturized pattern is formed.

The phase 105b can be removed by etching treatment utilizing the difference in etching rage or the like between the respective phases separated due to directed self-assembly. FIG. 6 illustrates a state after removing part of the phase 105b in the phase separation structure.

Examples of a method for removing part of the phase 105b in the phase separation structure of the directed self-assembled film include such known methods as reactive ion etching (RIE) such as chemical dry etching or chemical wet etching and physical etching such as sputter etching and ion beam etching. Among them, reactive ion etching (RIE) is preferable, and chemical dry etching using CF₄, O₂ gas or the like, and chemical wet etching (wet development) using an organic solvent such as methyl isobutyl ketone (MIBK) or 2-propanol (IPA), or a liquid etching solution such as hydrofluoric acid is more preferable.

### [Etching Step]

In this step, the substrate 101 is etched using a pattern such as a miniaturized pattern formed in the removing step. Thus, a substrate pattern can be formed.

The substrate can be patterned by etching the underlayer film 102 and the substrate 101 using, as a mask, the miniaturized pattern composed of part of the phase 105a of the directed self-assembled film remaining as a result of the removing step. After the patterning to the substrate 101 is completed, the phase used as the mask is removed from the substrate by dissolution treatment or the like, and finally, a substrate pattern (a patterned substrate) can be obtained. Examples of the pattern to be obtained include a line-and-space pattern and a hole pattern.

As a method of the etching, the same methods as the methods of etching disclosed as examples in the section of the removing step can be used. Among them, dry etching is preferable. The gas to be used for dry etching can be appropriately selected according to the material of the substrate. For example, when the substrate is made of a silicon material, a mixed gas of a fluorocarbon gas and SF₄ or the like can be used. When the substrate is a metal film, a mixed gas of BCl₃ and Cl₂ or the like can be used.

In addition, known technique can be appropriately used in the directed self-assembly lithography process.

The pattern obtained by the directed self-assembly lithography process is suitably used for semiconductor elements and the like, and further the semiconductor elements are widely used for LEDs, solar cells, and the like.

### EXAMPLES

Next, the examples of the present invention will specifically be described, but the present invention is not limited to these examples. Methods for measuring various physical property values will be described below.

### [Mw and Mn]

The Mw and the Mn of polymers were measured by gel permeation chromatography (GPC) using GPC columns manufactured by Tosoh Corporation (“G2000HXL” x 2, “G3000HXL” x 1, “G4000HXL” x 1) under the following conditions.

Eluant: tetrahydrofuran (manufactured by Wako Pure Chemical Industries, Ltd.)

Flow rate: 1.0 mL/min

Sample concentration: 1.0% by mass

Amount of sample injected: 100 μL

Column temperature: 40° C.

Detector: differential refractometer

Standard substance: monodisperse polystyrene

<Synthesis of polymer [A]>

The following monomers were used for the synthesis of the polymers for underlayer film formation.

M-1: styrene

M-2: methyl methacrylate

The following end treatment agents were used for the synthesis of the polymers for underlayer film formation.

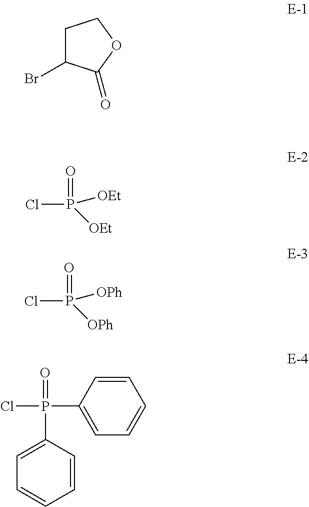

### [Synthesis Example 1] (Synthesis of Polymer (A-1))

A 500 mL flask reaction vessel was dried under reduced pressure, and then 100 g of tetrahydrofuran which had been subjected to dehydration treatment by distillation was charged into the vessel under a nitrogen atmosphere, and cooled to −78° C. Thereafter, 1.0 g of a 1 N sec-butyllithium (sec-BuLi) solution in cyclohexane was charged, and then 10.7 g of styrene which had been subjected to dehydration treatment by distillation was added dropwise over 30 minutes. After completion of the dropwise addition, the resulting mixture was subjected to a reaction for 120 minutes, and then 0.2 g of E-2 was charged as an end treatment agent and the resulting mixture was subjected to a reaction for 30 minutes.

The polymerization reaction liquid was heated to room temperature, and the resulting polymerization reaction liquid was concentrated and replaced with propylene glycol methyl ether acetate (PGMEA). Then, 1,000 g of a 2% by mass aqueous solution of oxalic acid was charged and the resulting mixture was stirred and then left to stand. Thereafter, the lower layer, i.e., an aqueous layer was removed. This operation was repeated three times to remove Li salts, and then 1,000 g of ultrapure water was charged, the resulting mixture was stirred, and then the lower layer, i.e., an aqueous layer was removed. This operation was repeated three times to remove oxalic acid, and then the resulting solution was concentrated. Thereafter, the mixture was added dropwise into 500 g of methanol to precipitate a polymer. The polymer collected by through vacuum filtration was washed twice with methanol, and then dried at 60° C. under reduced pressure, affording a white polymer (A-1).

The polymer (A-1) obtained had an Mw of 8,800 and an Mw/Mn of 1.12.

### [Synthesis Examples 2 to 3 and 7 to 8] (Synthesis of Polymers (A-2 to 3 and 7 to 8))

Polymers (A-2 to 3 and 7 to 8) shown in Table 1 below were also synthesized using the corresponding end treatment agents in the same manner as in Synthesis Example 1. The polymer (A-8) was further hydrolyzed, and the end structure thereof was thereby converted.

### [Synthesis Example 4] (Synthesis of Polymer (A-4))

A 500 mL flask reaction vessel was dried under reduced pressure, and then 100 g of tetrahydrofuran subjected to dehydration treatment by distillation, 0.66 g of diphenylethylene, and a 2.3% lithium chloride (LiCl) solution in tetrahydrofuran were charged into the vessel under a nitrogen atmosphere, and the mixture was cooled to −78° C. Thereafter, 1.2 g of a 1 N sec-butyllithium (sec-BuLi) solution in cyclohexane was charged, and then 12.3 g of methyl methacrylate subjected to dehydration treatment by distillation was added dropwise over 30 minutes. After completion of the dropwise addition, the resulting mixture was subjected to a reaction for 120 minutes, and then 0.2 g of E-2 was charged as an end treatment agent and the resulting mixture was subjected to a reaction for 30 minutes.

The polymerization reaction liquid was heated to room temperature, and the resulting polymerization reaction liquid was concentrated and replaced with propylene glycol methyl ether acetate (PGMEA). Then, 1,000 g of a 2% by mass aqueous solution of oxalic acid was charged and the resulting mixture was stirred and then left to stand. Thereafter, the lower layer, i.e., an aqueous layer was removed. This operation was repeated three times to remove Li salts, and then 1,000 g of ultrapure water was charged, the resulting mixture was stirred, and then the lower layer, i.e., an aqueous layer was removed. This operation was repeated three times to remove oxalic acid, and then the resulting solution was concentrated. Thereafter, the mixture was added dropwise into 500 g of methanol to precipitate a polymer. The polymer collected by through vacuum filtration was washed twice with methanol, and then dried at 60° C. under reduced pressure, affording a white polymer (A-4).

The polymer (A-4) obtained had an Mw of 9,500 and an Mw/Mn of 1.15.

### [Synthesis Examples 5 to 6 and 9] (Synthesis of Polymers (A-5 to 6 and 9))

Polymers (A-5 to 6 and 9) shown in Table 1 below were also synthesized using the corresponding end treatment agents in the same manner as in Synthesis Example 4.

### [Synthesis Example 10] (Synthesis of Block Copolymer)

A 500 mL flask reaction vessel was dried under reduced pressure, and then 200 g of THF subjected to dehydration treatment by distillation was charged into the vessel under a nitrogen atmosphere, and cooled to −78° C. Thereafter, 0.40 mL of a 1 N sec-butyllithium (sec-BuLi) solution of in cyclohexane was charged into the THF, and then 22.1 mL of styrene subjected to adsorption filtration with silica gel and dehydration treatment by distillation in order to remove a polymerization inhibitor was added dropwise over 30 minutes while being careful not to raise the internal temperature of the reaction solution to −60° C. or higher. After stirring for 30 minutes, 0.15 mL of 1,1-diphenylethylene and 1.42 mL of a 0.5 N lithium chloride solution in THF were added. Furthermore, in order to remove a polymerization inhibitor, adsorption filtration with silica gel and dehydration treatment by distillation were carried out. 18.0 mL of methyl methacrylate was added dropwise to the solution over 30 minutes, and then the mixture was reacted for 120 minutes. Thereafter, 1 mL of methanol was charged as an end terminator and a termination reaction of a polymerization end was carried out. The reaction solution was heated to room temperature, and the resulting reaction solution was concentrated and replaced with MIBK. Thereafter, 1,000 g of a 2% by mass aqueous solution of oxalic acid was charged and stirred, and the mixture was left at rest, and then the Li salt was removed by an operation of removing the lower aqueous layer. Thereafter, 1,000 g of ultrapure water was charged and stirred, oxalic acid was then removed by an operation of removing the lower aqueous layer. The resulting solution was concentrated and added dropwise to 500 g of methanol to precipitate a polymer, and the solid was collected with a Buchner funnel. Next, the solid was washed with cyclohexane, and the solid was collected again with a Buchner funnel. This solid was dried under reduced pressure at 60° C., affording 37.4 g of a white block copolymer (X-1).

This block copolymer (X-1) had an Mw of 58,600, an Mn of 57,000, and an Mw/Mn of 1.03. As a result of 1H-NMR analysis, in the block copolymer (X-1), the contents of the repeating unit (PS) derived from styrene and the repeating unit (PMMA) derived from methyl methacrylate were 50.0% by mass (50.0 mol %) and 50.0% by mass (50.0 mol %), respectively. It is noted that the block copolymer (X-1) was a diblock copolymer.

TABLE 1

| | | | End | | | |
|---|---|---|---|---|---|---|
| Synthesis | Poly- | Mono- | treatment | Hy- | | Mw/ |
| Example | mer | mer | agent | drolysis | Mn | Mn |
| Synthesis | A-1 | M-1 | E-1 | — | 8600 | 1.15 |
| Example 1 | | | | | | |
| Synthesis | A-2 | M-1 | E-2 | — | 8800 | 1.12 |
| Example 2 | | | | | | |
| Synthesis | A-3 | M-1 | E-2 | ◯ | 8500 | 1.11 |
| Example 3 | | | | | | |
| Synthesis | A-4 | M-1 | E-3 | — | 15100 | 1.06 |
| Example 4 | | | | | | |
| Synthesis | A-5 | M-1 | E-4 | — | 7100 | 1.07 |
| Example 5 | | | | | | |
| Synthesis | A-6 | M-2 | E-1 | — | 10100 | 1.08 |
| Example 6 | | | | | | |
| Synthesis | A-7 | M-2 | E-2 | — | 9500 | 1.15 |
| Example 7 | | | | | | |
| Synthesis | A-8 | M-2 | E-3 | — | 10000 | 1.08 |
| Example 8 | | | | | | |
| Synthesis | A-9 | M-2 | E-4 | — | 12100 | 1.06 |
| Example 9 | | | | | | |

### <Preparation of Composition for Underlayer Film Formation>

The components used for the preparation of compositions for underlayer film formation are described below.

### [Component [A]]

A-1 to A-9: Solutions containing 10% by mass of the polymers (A-1) to (A-9) synthesized in Synthesis Examples 1 to 9 above.

### [Solvent [B]]

B-1: propylene glycol monomethyl ether acetate

B-2: butyl acetate

B-3: cyclohexanone

### [Example 1] (Preparation of Composition for Underlayer Film Formation (S-1))

100 parts by mass of a solution containing 10% by mass of (A-1) as compound [A] and 374 parts by mass of (B-1) as solvent [B] were mixed and dissolved, affording a mixed solution. The resulting mixed solution was filtered through a membrane filter having a pore size of 0.1 Lm to prepare a composition for underlayer film formation (S-1).

### Examples 2 to 9 and Comparative Examples 1 to 3

Compositions for underlayer film formation (S-2) to (S-9) and (CS-1) to (CS-3) were prepared in the same manner as in Example 1 except that the components with the types and the blending amounts shown in Table 1 below were used.

TABLE 2

| | | Composition for underlayer film formation | | | | | | | | | | |
|---|---|---|---|---|---|---|---|---|---|---|---|---|
| | | S-1 | S-2 | S-3 | S-4 | S-5 | S-6 | S-7 | S-8 | CS-1 | CS-2 | CS-3 |
| Solution | A-1 | | | | | | | | | 100 | | |
| containing | A-2 | 100 | | | | | | 100 | 100 | | | |
| compound [A] | A-3 | | | | | | | | | | 100 | |
| (parts by | A-4 | | 100 | | | | | | | | | |
| mass) | A-5 | | | 100 | | | | | | | | |
| | A-6 | | | | | | | | | | | 100 |
| | A-7 | | | | 100 | | | | | | | |
| | A-8 | | | | | 100 | | | | | | |
| | A-9 | | | | | | 100 | | | | | |
| Compound [B] | B-1 | 374 | 374 | 374 | 374 | 374 | 374 | | 235 | 374 | 374 | 374 |
| (parts by | B-2 | | | | | | | 374 | | | | |
| mass) | B-3 | | | | | | | | 139 | | | |

### <Underlayer Film Formation Treatment>

Using each of the compositions for underlayer film formation prepared above, a coating film having a film thickness of 50 nm was formed on a surface of a tungsten substrate, and baking was conducted at 170 to 200° C. for 180 seconds. Subsequently, in order to remove the compound [A] not interacting with the substrate, the baked resultant was washed with propylene glycol methyl ether acetate (PGMEA), and then the substrate was dried at room temperature for 30 seconds, and thus underlayer film formation treatment of the substrate was conducted.

### <Evaluation>

The contact angle of a surface of the substrate subjected to the underlayer film formation treatment was measured and used as the substrate adsorption property (deg). The larger the measured value, the better the substrate adsorption property.

### [Contact Angle]

In the measurement of the contact angle of a surface of each of the substrates subjected to the underlayer film formation treatment, using a contact angle meter (“DSA 30S” manufactured by KLUSS GmbH), a 2 μL water droplet was formed on the substrate under an environment specified by a room temperature: 23° C., a humidity: 45%, and normal pressure, and the contact angle was rapidly measured. The contact angle measurements are shown in Table 3.

### [Non-Corrosiveness to Substrate]

Using each of the compositions for underlayer film formation prepared above, a coating film having a thickness of 50 nm was formed on a surface of a copper substrate, and left at rest for 24 hours. Subsequently, the surface of the substrate was washed with propylene glycol methyl ether acetate (PGMEA), and then was dried at room temperature for 30 seconds. Thus underlayer film formation treatment of the substrate was carried out. The surface of the substrate was observed using a scanning electron microscope (“S-4800” manufactured by Hitachi, Ltd.), and a case where corrosiveness to the Cu substrate was observed was evaluated as “X”, and a case where no corrosion of the Cu substrate was observed was evaluated as “◯”.

### [Favorableness of Pattern]

Onto a silicon wafer substrate with a surface on which an underlayer film and a neutralization film had been formed, a composition for directed self-assembled film formation prepared by dissolving 1.3 g of the block copolymer (X-1) in 98.7 g of propylene glycol monomethyl ether acetate was applied such that a directed self-assembled film to be formed would have a thickness of 30 nm, and thus a coating film was formed. Then, the coating film was heated at 250° C. for 10 minutes to undergo phase separation, and a microdomain structure was thereby formed. The formed pattern was observed with a scanning electron microscope (“S-4800” manufactured by Hitachi, Ltd.) to evaluate the favorableness of the pattern.

The favorableness of a pattern was evaluated as “◯ (good)” when clear phase separation was confirmed, and was evaluated as “X (poor)” when phase separation was not observed or phase separation was incomplete and had defects.

TABLE 3

| | | | | | Favorableness |
|---|---|---|---|---|---|
| | Composition for | Baking | | Existence of | of phase |
| | underlayer film | temperature | Contact | substrate | separation |
| | formation | [° C.] | angle [deg] | corrosion | pattern |
| Example 1 | S-1 | 200 | 82.4 | ∘ | ∘ |
| Example 2 | S-1 | 230 | 86.9 | ∘ | ∘ |
| Example 3 | S-2 | 200 | 81.7 | ∘ | ∘ |
| Example 4 | S-3 | 200 | 85.9 | ∘ | ∘ |
| Example 5 | S-4 | 200 | 63.5 | ∘ | ∘ |
| Example 6 | S-4 | 230 | 65.4 | ∘ | ∘ |
| Example 7 | S-5 | 200 | 59.7 | ∘ | ∘ |
| Example 8 | S-6 | 200 | 61.5 | ∘ | ∘ |
| Example 9 | S-7 | 200 | 63.0 | ∘ | ∘ |
| Example 10 | S-8 | 200 | 65.1 | ∘ | ∘ |
| Comparative | CR-1 | 200 | 50.2 | ∘ | x |
| Example 1 | | | | | |
| Comparative | CR-2 | 200 | 89.6 | x | ∘ |
| Example 2 | | | | | |
| Comparative | CR-3 | 200 | 48.3 | ∘ | x |
| Example 3 | | | | | |

As shown in Table 3, as a result of the evaluation, it was demonstrated that in all of the substrates prepared in Examples 1 to 10 using a composition for underlayer film formation of the embodiment of the present invention, the composition was superior in adsorbability to a metal substrate, superior in non-corrosiveness to a substrate, and capable of well forming a phase separation pattern. On the other hand, in all of the substrates prepared in Comparative Examples 1 to 3, it was poor in well achieving both the adsorbability to a metal substrate and the non-corrosiveness to a substrate.

Using the directed self-assembly lithography process using the composition for underlayer film formation of the present embodiment of the invention, a phase separation structure due to directed self-assembly can be favorably formed. Therefore, they can be suitably used in a lithography process in the manufacture of various electronic devices such as semiconductor devices and liquid crystal devices, which are required to be further miniaturized.

Obviously, numerous modifications and variations of the present invention(s) are possible in light of the above teachings. It is therefore to be understood that within the scope of the appended claims, the invention(s) may be practiced otherwise than as specifically described herein.

1. A composition comprising:
at least one polymer which is a polymer represented by formula (1), a polymer represented by formula (2), or both; and
a solvent, 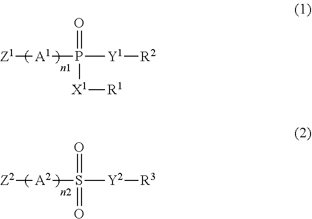
in the formulas (1) and (2),
A¹ and A² are each independently a structural unit having 2 or more carbon atoms; a plurality of A's are the same or different and a plurality of A²s are the same or different;
n1 and n2 are each independently an integer of 2 to 500;
R¹, R², and R³ are each independently an organic group having 1 or more carbon atoms, or R¹ and R² taken together represent a ring together with X¹, Y¹, and P; R¹ and R² are the same or different;
X¹, Y¹, and Y² are each independently a single bond, —O—, or —NR⁴—; R⁴ is an organic group having 1 or more carbon atoms; and
Z¹ and Z² are each independently hydrogen or an organic group having 1 to 15 carbon atoms.

2. The composition according to claim 1, wherein the polymer represented by the formula (1) and the polymer represented by the formula (2) are each a homopolymer, a random copolymer, or an alternating copolymer.

3. The composition according to claim 1, wherein A¹ in the formula (1) and A² in the formula (2) each comprise, as a monomer unit, at least one selected from the group consisting of a structural unit derived from styrene, a structural unit derived from a (meth)acrylate ester, and a structural unit derived from vinylpyridine.

4. The composition according to claim 1, wherein the composition is suitable for an underlayer film formation on a silicon-containing substrate in a directed self-assembly lithography process.

5. The composition according to claim 1, wherein the composition is suitable for an underlayer film formation treatment on a metal-containing film in a directed self-assembly lithography process.

6. An underlayer film of a directed self-assembled film in a directed self-assembly lithography process, formed from the composition according to claim 1.

7. A directed self-assembly lithography process comprising:
forming an underlayer film by applying the composition according to claim 1 directly or indirectly on one surface of a substrate;
applying a composition for directed self-assembled film formation to a surface of the underlayer film on a side opposite the substrate to form a coating film on the underlayer film;
phase-separating the coating film to form a directed self-assembled film having a plurality of phases; and
removing at least part of the plurality of phases of the directed self-assembled film to form a pattern.

8. The directed self-assembly lithography process according to claim 7, further comprising etching the substrate using the pattern as a mask.

9. The directed self-assembly lithography process according to claim 7, further comprising, prior to applying the composition for directed self-assembled film formation,
forming a pre-pattern having a recess on a surface side of the underlayer film or the substrate, the surface side being a side in which the directed self-assembled film is to be formed,
wherein the composition for directed self-assembled film formation is filled into the recess of the pre-pattern by applying the composition for directed self-assembled film to the surface of the underlayer film.

10. The directed self-assembly lithography process according to claim 7, wherein the substrate is a silicon-containing substrate or a substrate having a metal-containing film formed thereon.
